(19) United States
(12) Patent Application Publication
(10) Pub. No.: US 2023/0207726 A1
(43) Pub. Date: Jun. 29, 2023

(54) LIGHT GENERATION FROM RESONANT INELASTIC TUNNELING JUNCTIONS

(71) Applicant: The Regents of the University of California, Oakland, CA (US)

(72) Inventors: Zhaowei Liu, San Diego, CA (US); Haoliang Qian, San Diego, CA (US)

(21) Appl. No.: 18/000,078

(22) PCT Filed: May 28, 2021
(86) PCT No.: PCT/US21/34929

§ 371 Date: Nov. 28, 2022

Related U.S. Application Data
(60) Provisional application No. 63/031,428, filed on May 28, 2020.

(51) Int. Cl. H01L 33/06; H01L 33/32; H01L 33/12

(52) U.S. Cl. CPC H01L 33/06; H01L 33/32; H01L 33/12

(57) ABSTRACT

An apparatus, a method, and an optical device for generating light. A conductive quantum well junction is positioned between a first electrode and a second electrode. The conductive quantum well junction is configured to enter into a resonant state to inelastically tunneling one or more electrons. The conductive quantum well junction may include a first dielectric layer, a third conductive layer, and a second dielectric layer. The third conductive layer may be positioned between the first dielectric layer and the second dielectric layer. The first dielectric layer may be coupled to the second electrode and the second dielectric layer is coupled to the first electrode.

### CROSS-REFERENCE TO RELATED APPLICATIONS

The present application claims priority to U.S. Provisional Patent Appl. No. 63/031,428 to Liu et al., filed May 28, 2020, entitled “Light Generation From Resonant Inelastic Tunneling Junctions” and incorporates its disclosure herein by reference in its entirety.

### TECHNICAL FIELD

This disclosure relates generally to optics, and in particular, to generation of light from resonant inelastic tunneling junctions.

### BACKGROUND

Plasmonics or nanoplasmonics involve generation, detection, and manipulation of signals at optical frequencies along metal-dielectric interfaces in the nanometer scale. Plasmonics allow for miniaturization of optical devices and are used in sensing, microscopy, optical communications, and bio-photonic applications. While conventional photonic elements are able to carry information in excess of 1,000 times of electronic components, they are large (due to optical diffraction limit) and difficult to integrate with modern-day nanoelectronics. To combine small dimensions of nanoelectronics with the fast operating speed of optics via plasmonics, on-chip electronic-plasmonic circuitry is required.

### SUMMARY

In some implementations, the current subject matter relates to an apparatus (e.g., a surface plasmon source). The apparatus may include a conductive quantum well junction that may be positioned between a first electrode and a second electrode. The conductive quantum well junction may be configured to enter into a resonant state to inelastically tunneling one or more electrons (such as through application of electrical energy from an external source).

In some implementations, the current subject matter may include one or more of the following optional features. The conductive quantum well junction may include a first dielectric layer, a third conductive layer, and a second dielectric layer. The third conductive layer may be positioned between the first dielectric layer and the second dielectric layer. The first dielectric layer may be coupled to the second electrode and the second dielectric layer is coupled to the first electrode.

In some exemplary implementations, the first electrode may be an indium-tin-oxide layer and the second electrode is a titanium-nitride layer.

In some exemplary implementations, the third metallic layer may be a titanium-nitride layer.

The apparatus may also include an energy coupling device that may be positioned between the conductive quantum well junction and the first electrode. The energy coupling device may be configured to support inelastic tunneling of the one or more electrons in the resonant state. Alternatively, or in addition to, the energy coupling device may be positioned between the conductive quantum well junction and the second electrode. Moreover, one or both of the first and second electrodes may include the energy coupling device. As stated above, the energy coupling device includes one or more silver nanorods, metallic nanorods, conductive nanorods, and/or any combination thereof.

In some implementations, the second electrode may be disposed on a substrate. The substrate may be a sapphire substrate and/or any material substrate.

An external energy source may be configured to supply a predetermined potential to cause the conductive quantum well junction to enter into the resonant state for inelastically tunneling the one or more electrons. The external energy source may be coupled to first and second electrodes.

In some implementations, the apparatus may also include a fourth metallic layer and a dielectric layer disposed between at least a portion of the first electrode and the conductive quantum well junction. An external energy source may be coupled to the second electrode and the fourth metallic layer.

In some implementations, the conductive quantum well junction may be configured to prevent elastic tunneling of one or more electrons. The inelastic tunneling of the electrons through the conductive quantum well junction layer may be configured to generate light in at least one of the following spectrums: a visible light spectrum, a near infrared light spectrum, mid-infrared light spectrum, and any combination thereof.

In some implementations, the current subject matter relates to an optical apparatus. The apparatus may include a plasmonic device. The plasmonic device may include a conductive quantum well junction positioned between a first electrode and a second electrode. The conductive quantum well junction may be configured to enter into a resonant state to inelastically tunneling one or more electrons. The optical apparatus may also include an external electrical energy source configured to supply a predetermined potential to cause the conductive quantum well junction to enter into the resonant state for inelastically tunneling the one or more electrons. The inelastic tunneling of the electrons through the plasmonic device may be configured to generate light in at least one of the following spectrums: a visible light spectrum, a near infrared light spectrum, mid-infrared light spectrum, and any combination thereof.

In some implementations, the optical apparatus may include an energy coupling device positioned between the conductive quantum well junction and the first electrode. The energy coupling device may support inelastic tunneling of the electrons in the resonant state. Further, the plasmonic device may include at least one of the following: a nanoLED, a nanolaser, a nanojunction, a plasmonic source, an on-chip electrically-driven plasmonic circuit, a waveguide, a router, a modulator, a detector, and any combination thereof. Moreover, the optical apparatus may include a plurality of plasmonic devices disposed on a single substrate.

In some implementations, the current subject matter relates to a method for generating light using a plasmonic device. The method may include providing a conductive quantum well junction positioned between a first electrode and a second electrode, applying an electrical potential across the conductive quantum well junction to cause the conductive quantum well junction to enter into a resonant state, inelastically tunneling one or more electrons through the metallic quantum well junction in the resonant state, and generating light in at least one of the following spectrums: a visible light spectrum, a near infrared light spectrum, mid-infrared light spectrum, and any combination thereof.

The details of one or more variations of the subject matter described herein are set forth in the accompanying drawings and the description below. Other features and advantages of the subject matter described herein will be apparent from the description and drawings, and from the claims. While certain features of the currently disclosed subject matter are described for illustrative purposes in relation to optical edge detection, it should be readily understood that such features are not intended to be limiting. The claims that follow this disclosure are intended to define the scope of the protected subject matter.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates an exemplary resonant inelastic electron tunneling system, according to some implementations of the current subject matter;

FIG. 2 illustrates an exemplary electron subband diagram of the metallic quantum well junction, according to some implementations of the current subject matter;

FIG. 3 illustrates another exemplary electron subband diagram of the metallic quantum well junction, according to some implementations of the current subject matter;

FIG. 4 illustrates a structural cross-section of an exemplary resonant inelastic electron tunneling surface plasmon (RIET SP) source apparatus, according to some implementations of the current subject matter;

FIGS. 5a-b illustrate an exemplary scanning electron microscope image of a top view of multiple resonant inelastic electron tunneling (RIET) devices (as shown in FIG. 4) and an image of a top view of a single RIET device (shown in FIG. 4), according to some implementations of the current subject matter;

FIG. 5c illustrates an exemplary scanning electron microscope image showing a homogenously distributed array of silver nanorods (AgNRs), according to some implementations of the current subject matter;

FIG. 5d illustrates an exemplary scanning electron microscope image of a single AgNR, according to some implementations of the current subject matter;

FIG. 6a illustrates an exemplary plot comparing experimental electro-optical response of the RIET devices, according to some implementations of the current subject matter;

FIG. 6b illustrates an exemplary plot showing voltage dependence of the corresponding SP emission power, according to some implementations of the current subject matter;

FIG. 6c illustrates an exemplary plot showing voltage dependence of the external quantum efficiency of the RIET SP source, according to some implementations of the current subject matter;

FIG. 7 illustrates exemplary SP emission spectra plots of the current subject matter's RIET device at various voltages, according to some experimental implementations of the current subject matter; and

FIG. 8 illustrates an exemplary, non-limiting experimental process for fabricating resonant inelastic electron tunneling devices, according to some implementations of the current subject matter

### DETAILED DESCRIPTION

One or more implementations of the current subject matter relate to methods, systems, articles of manufacture, and the like that may, among other possible advantages, provide for systems, devices, and/or methods for generating light from resonant inelastic tunneling junctions.

In some implementations, the current subject matter relates to an apparatus for generating light from resonant inelastic tunneling junction. The apparatus may be configured as an on-chip plasmonic circuit, and/or an electrically-driven surface plasmon (SP) source that may be enabled by resonant inelastic electron tunneling (RIET). Inelastic electron tunneling process may occur between two electrodes and may allow for transfer of energy to molecular vibrations through electron-vibration interaction. This process may further occur at a threshold bias voltage that may correspond to a vibrational energy, which may lead to an opening of a new conductance channel. The current subject matter apparatus may include a first or lower layer/electrode that may be positioned on a substrate (e.g., sapphire substrate and/or any other desired substrate), a second or upper layer/electrode, and a well junction layer positioned between the first layer/electrode and the second layer/electrode. The apparatus may further include plasmonic mode of energy rods disposed on the well junction layer. The rods may be disposed on top of the well junction layer. By way of a non-limiting example, the rods may be silver nanorods (AgNR), but, as can be understood, can be any other type of material. The first and second layers/electrodes may be conductive (e.g., metallic, etc.) layers/electrodes, such as, for example, titanium-nitride (TiN) for the first layer and indium-tin-oxide (ITO) for the second layer. The well junction layer may be a conductive (e.g., metallic, etc.) quantum well (MQW) tunnel junction layer, which may include a conductive (e.g., metallic, etc.) layer (e.g., TiN layer) positioned between two insulator (aluminum oxide (Al₂O₃)) layers. The apparatus may be structured as a metal-insulator-metal-insulator-metal (MIMIM) that may be configured to impede elastic tunneling of electrons across this multiplayer structure by using the two insulator layers, while facilitating inelastic electron tunneling via the resonant electron states of the conductive quantum well junction layer.

The MQW tunnel junction may be biased via the second or upper ITO conducting layer and the first or lower TiN metallic layer. Electrons may inelastically tunnel through the MQW tunnel junction by coupling to a plasmonic mode of energy that may be supported by the nanorods (AgNRs) disposed on top of the MQW tunnel junction. In its resonant state, the surface plasmons may be emitted with energy in a visible/near-infrared (NIR)/mid-infrared spectral range.

On-chip plasmonic circuitry provides a promising route to meet the ever-increasing requirement for device density and data bandwidth in information processing. As one of the key building blocks, electrically-driven nanoscale plasmonic sources, such as nanoLEDs, nanolasers, and/or nanojunctions, have attracted intense interest in recent years. Surface plasmon sources based on inelastic electron tunneling (IET) have demonstrated usefulness in these application due to its ultrafast quantum-mechanical tunneling response and tunability. However, the IET-based SP sources are limited by approximately 10% external quantum efficiency (EQE).

The on-chip electrically-driven plasmonic circuitries combine small device footprint (<10-nm feature size) of electronic circuitry and large information capacity (>100-THz bandwidth) of a photonic network. A variety of plasmonic building blocks have been demonstrated ranging from sources, waveguides, routers, modulators, to detectors. So far, the widely used electrical source of surface plasmons relies on a two-step process, i.e., generation of photons by electrically-triggered spontaneous emission and the subsequent SP excitation via near-field coupling of the generated photons. While the Purcell effect (i.e., enhancement of a quantum system's spontaneous emission rate by its environment) accelerates this spontaneous-emission process, the modulation speed of the plasmonic sources is limited (>1 ps). On the other side, the modulation rate of plasmonic nanolasers (i.e., light sources that rely on the stimulated emission process) is also within the sub-THz range. In addition, the plasmonic nanolasers' emissions are typically fixed at one specific frequency by their design. Direct electrical excitation of SPs via inelastic electron tunneling in metal-insulator-metal (MIM) junctions has been used as an ultrafast source to drive the integrated plasmonic circuitries. Since this quantum-mechanical tunnel event is governed by Heisenberg's uncertainty principle, IET-based plasmonic sources could have a temporal response as fast as few fs at the visible/NIR/mid-infrared frequencies. In terms of the electro-plasmon transduction efficiency, an external quantum efficiency of approximately 10% was achieved by tailoring the local density of optical states (LDOS) of an IET source, which is on par with EQEs of SP sources based on nanoscale light-emitting diodes and much higher than EQEs obtained from silicon nanocrystals or carbon nanotubes. Moreover, the emission spectrum of IET-based SP sources ranges from the visible all the way to the infrared frequencies, and can be pre-designed by the SP modes and post-tuned by external voltages. Thus, an IET-enabled electrically-driven SP source can address requirements in bandwidth, efficiency, and tunability associated with plasmonic circuitries.

As stated above, conventionally, optical engineering of the LDOS of IET sources has been limited by quantum-mechanical effects (e.g., 10% of EQE), such as electron tunneling and nonlocal screening in plasmonic nanostructures. To address this issue, in some implementations, the current subject matter's on-chip electrically-driven SP sources may be capable of generating EQEs of up to 30% at the visible/NIR/mid-infrared frequencies, and which are enabled by resonant inelastic electron tunneling. As stated above, the RIET may supported by a TiN/Al₂O₃ metallic quantum well (MQW) heterostructure, while monocrystalline silver nanorods (AgNRs) may be used for the SP generation and guiding. This RIET approach may be capable of generating the EQEs close to unity (100%), thereby enabling a variety of SP sources for high-performance plasmonic circuitry.

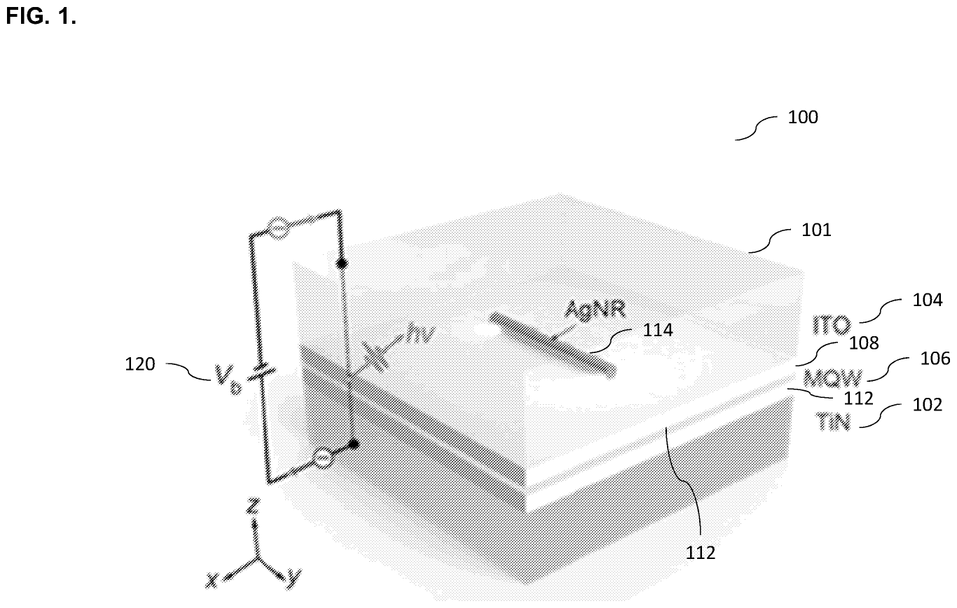

FIG. 1 illustrates an exemplary resonant inelastic electron tunneling system 100, according to some implementations of the current subject matter. The system 100 may include an apparatus 101 and an electrical source 120. The apparatus 101 may be disposed on a substrate (not shown in FIG. 1). The apparatus 101 may include a first or a lower layer/electrode 102, a conductive (e.g., metallic, etc.) quantum well (MQW) junction layer 106, and a second or an upper layer/electrode 104. The MQW junction layer 106 may be positioned between, coupled to, and or biased through the first layer 102 and the second layer 104. The MQW junction layer 106 may further include a first insulating layer 108, a second insulting layer 110 and a conductive (e.g., metallic, etc.) layer 112 positioned between and coupled to the first and second insulating layers 108 and 110. One or more nanorods 114 (e.g., silver nanorods (AgNRs)) may be positioned on top and/or on the bottom of the MQW junction layer 106. Alternatively, or in addition to, the nanorods may be part of and/or incorporated into the first and/or second layers/electrodes 102, 104.

In some exemplary implementations, the AgNRs 114 may be encapsulated in a shell (e.g., polyethylene glycol (PEG) ligand shell). The thickness of the ligand shell may be approximately 1-2 nm (and/or any other desired thickness). The shell may electrically insulate the AgNRs 114 from the external circuitry. Such isolation of ligand shell may be utilized to demonstrate an IET-based light source, where the ligand shell of silver nanocubes is used as the electron tunneling barrier.

The upper layer/electrode 104 may be a conductive layer (e.g., an indium-tin-oxide (ITO) layer, a metallic layer, etc.). The lower layer/electrode 102 may be a conductive layer (e.g., titanium-nitride (TiN) layer, a metallic layer, etc.). The first and second layers 108, 110 of the MQW junction layer 106 may be insulating and/or dielectric layers (e.g., aluminum oxide (Al₂O₃)). The layer 112 may be a conductive layer (e.g., TiN layer, a metallic layer, etc.). The layer 112 may be an ultrathin metal film (e.g., approximately 1.4 nanometers (nm) TiN) with atomically flat interfaces between the two dielectric layers 108 and 110 (e.g., each being approximately 10 nm).

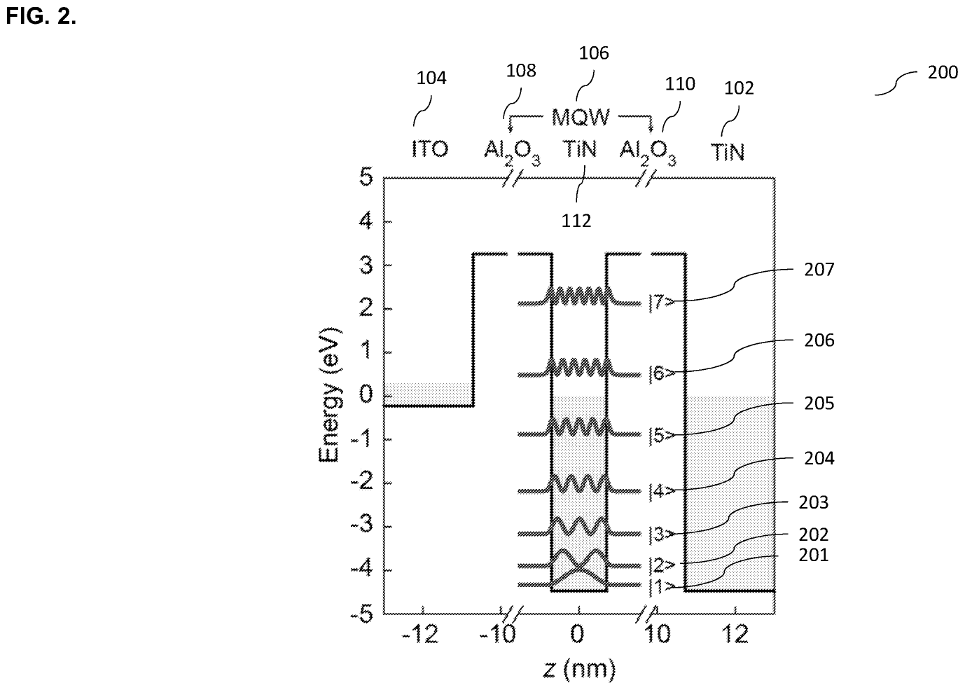

The apparatus 101, with alternating conducting and dielectric layers, may be deemed as a heterostructure for the purposes of the quantum size effect. The conduction band of the ultrathin MQW junction layer 106 may be split into one or more resonant electron subbands. FIG. 2 illustrates an exemplary electron subband diagram 200 of the MQW junction layer 106, according to some implementations of the current subject matter. As shown in FIG. 2, there may be seven discrete states 201-207 (i.e., |1>, |2>, . . . |7>) provided by the MQW junction layer 106, which may be due to the layer's extremely high quantum well (QW) barrier (e.g., approximately 8 electron-volt (eV)). This may allow realization of the RIET at visible/NIR/mid-infrared frequencies, but also to tune it using large range of external voltages.

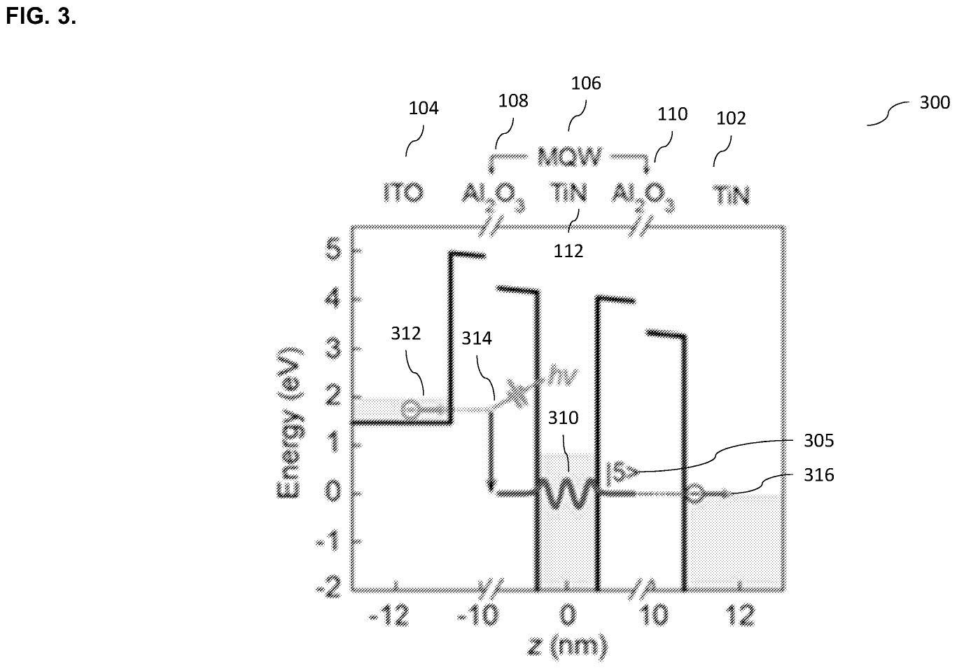

As shown in the electron subband diagram 300 in FIG. 3, the resonant inelastic electron tunneling process may be initiated when the resonant electron state 15) 305 of the MQW junction layer 106 is aligned with the Fermi level (defined by Fermi's golden rule governing transition rate (i.e., probability of a transition per unit time) from one energy eigenstate of a quantum system to a group of energy eigenstates in a continuum, as a result of a weak perturbation) of the TiN positive electrode layer 112. The alignment may be achieved by increasing a bias voltage (from electrical source 120 shown in FIG. 1) that is applied across apparatus 101. During the RIET process, electrons 312 in the ITO negative electrode layer 104 may tunnel, at 310, through the MQW junction layer 106 inelastically by coupling to a plasmonic mode of energy hv 314 supported by the nanorods (AgNRs) 114 that may be positioned on top of the MQW junction layer 106. Here, h is the Planck constant and v is the frequency. The resonant electron states provided by the high-quality MQW tunnel junction layer 106 may enable RIET process to generate light 316 in visible/NIR frequencies that may be used for highly efficient electrically-driven SP sources.

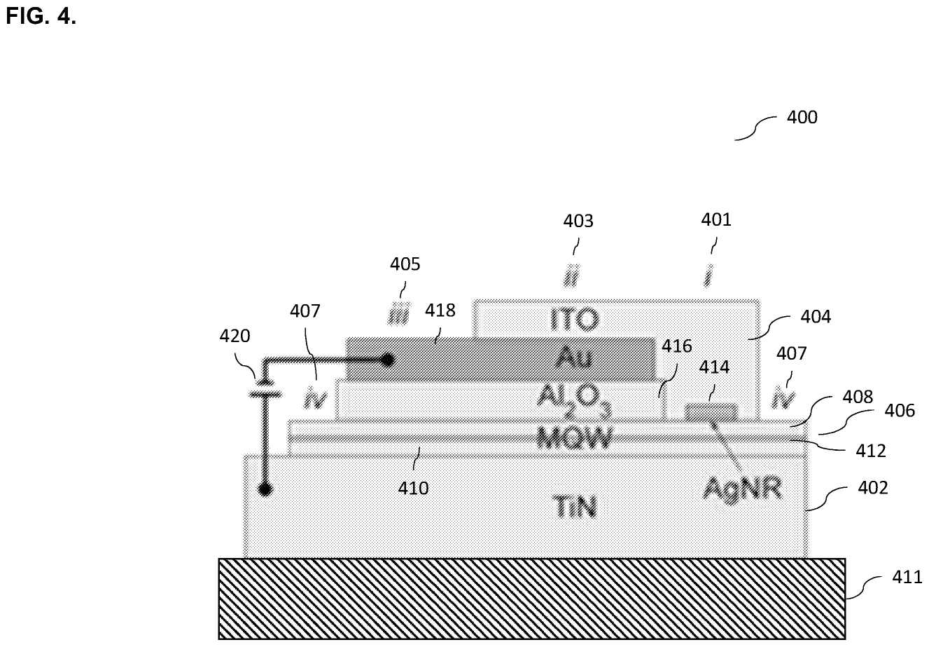

FIG. 4 illustrates a structural cross-section of an exemplary resonant inelastic electron tunneling surface plasmon (RIET SP) source apparatus 400, according to some implementations of the current subject matter. The apparatus 400 may include a substrate (e.g., sapphire or any other desired material) 401, a first or a bottom layer/electrode (e.g., TiN layer, a metallic layer, etc.) 402, a MQW junction layer 406, and a second or an upper layer/electrode (e.g., ITO layer, a metallic layer, etc.) 404. One or more nanorods (e.g., AgNRs) 414 may be positioned on top and/or on the bottom of the MQW junction layer 406. Alternatively, or in addition to, the nanorods may be part of and/or incorporated into the first and/or second layers/electrodes 402, 404. Further, a dielectric layer (e.g., Al₂O₃) 416 may be positioned on top of the MQW junction layer 406 with a conductive/metallic layer (e.g., gold (Au)) 418 positioned on top of the dielectric layer 416. layers 416, 418 may be sandwiched between the top layer 404 and the MQW junction layer 406.

The MQW junction layer 406 may be similar to layer 106 shown in FIG. 1. In particular, the layer 406 may include first and second dielectric layers 408, 410 (e.g., Al₂O₃) and a conductive layer (e.g., TiN layer, a metallic layer, etc.) 412. The layer 412 may be an ultrathin metal film with atomically flat interfaces between the two dielectric layers 408 and 410.

An electrical source 420 may also be biased across the apparatus 400. The electrical source 420 may be configured to supply potential for initiation of the resonant inelastic electron tunneling process.

As shown in FIG. 4, the apparatus 400 may be divided into four regions i 401, ii 403, iii 405, iv 407. The regions 401-407 may be used to carry out electrical pumping and an optical far-field measurements on a single device mesa. Electrons may be injected from an external circuitry/power source 420 into an Au layer 418 at region iii 405. Then, the electrons may be transported into the top ITO layer 404 at region ii 403 and may be accumulated on top of an MQW junction layer 406 at region i 401. As shown in FIG. 3, the electrons may tunnel inelastically through the MQW junction layer 406 by coupling to an AgNR SP mode. The electrons may then be transported back to the external circuitry 420 across the first layer (TiN) layer 402.

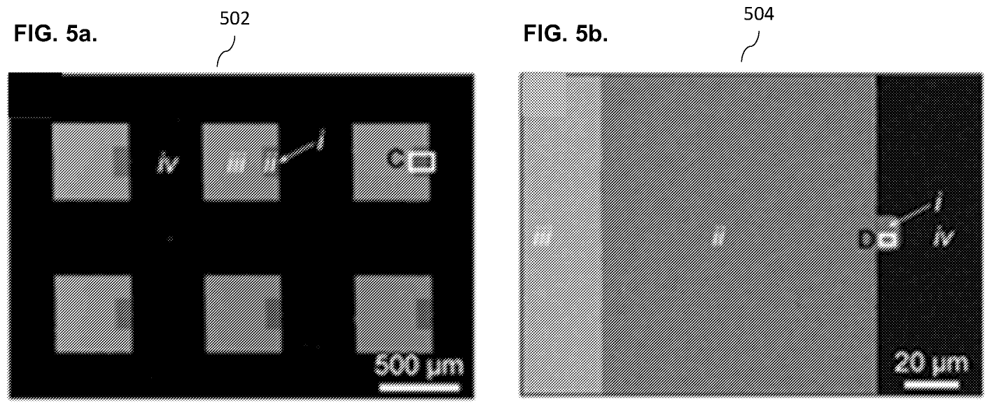

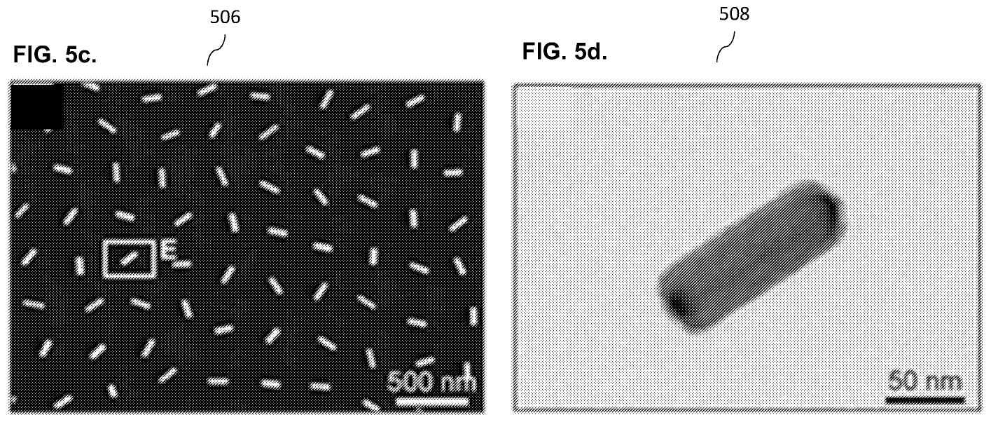

FIGS. 5a-b illustrate scanning electron microscope (SEM) image 502 (FIG. 5a) of top view of multiple RIET devices (shown in FIG. 4) and image 504 (FIG. 5b) of a top view of a single RIET device (shown in FIG. 4). As shown, the different device mesas may be separated by region iv 407, which may be useful in producing an integrative, scalable surface plasmon device. A small fraction of the generated SPs may be scattered off, e.g., converted to photons, from the AgNR to the far field through the top transparent ITO layer 404 (shown in FIG. 4) in the region i 401, thereby enabling an optical far-field measurement on the SP source.

In some exemplary implementations, monocrystalline AgNRs 414 may be used to support surface plasmons for the RIET device. FIG. 5c illustrates an exemplary SEM image 506 showing an array of AgNRs 414 homogenously distributed over region i 401 before deposition of the ITO layer 404. FIG. 5d illustrates an exemplary SEM image 508 of a single AgNR 414. The AgNRs 414, for example, may have a diameter of 40±5 nm and a length of 130±10 nm (as shown in FIG. 5d). The AgNRs 414, for example, may be organized into a loosely-packed monolayer at an air-water interface and then transferred on top of the MQW junction layer 406, using, for instance, Langmuir-Blodgett deposition, and/or any other technique.

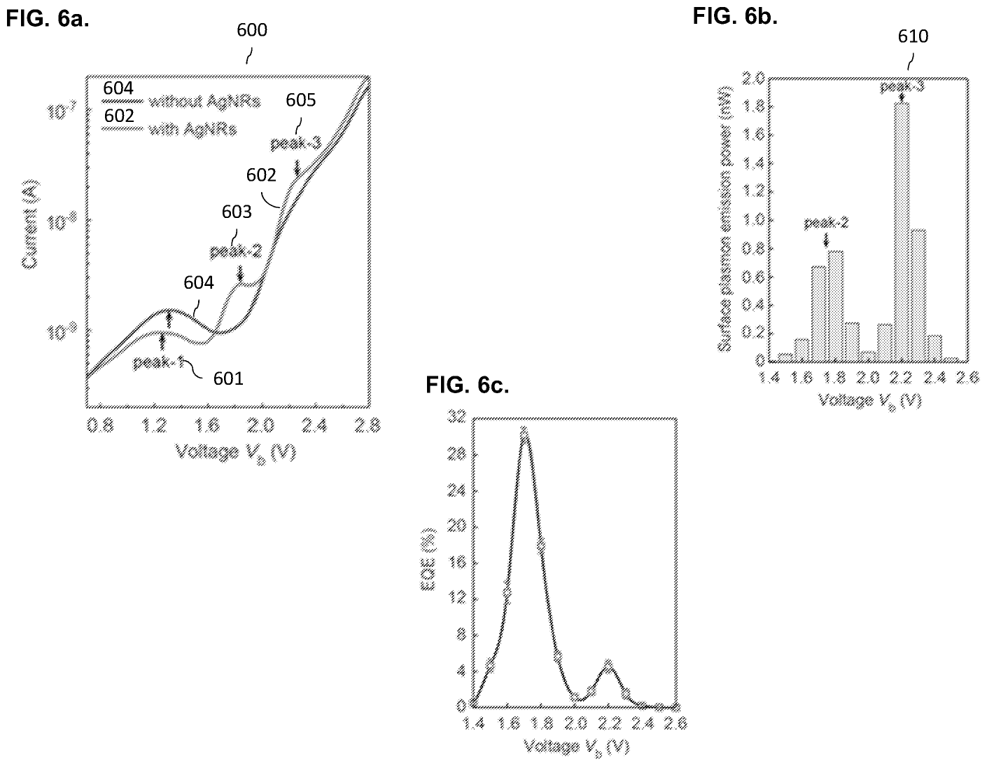

FIG. 6a illustrates an exemplary plot 600 comparing experimental electro-optical response of the RIET devices, one that includes the AgNRs and one that does not. The electro-optical response of the RIET device with AgNRs is illustrated by current-voltage (I-V) curve 602 and without AgNRs is illustrated by curve 604. A current peak (peak-1) 601 centered at approximately 1.3 V was observed for both devices. It gave rise to a negative differential resistance region, which is typical of a resonant tunneling diode, indicating that the fabricated MQW junction layers provide resonant electron states. This is further indicative of a resonant elastic electron tunneling (REET) process, which is unfavorable because it may severely reduce the SP generation efficiency. No REET process occurred at voltages above approximately 1.6 V, as can be seen from the I-V curve 604 of the control sample.

Apart from the low-voltage REET peak, two more current peaks (peak-2 605 and peak-3 607) at high voltage may be observed for the RIET device with AgNRs, as indicated by the curve 602 in FIG. 6a. The two high-voltage peaks may be caused by a large tunneling current accompanied by the RIET process. This is evidenced by the plot 610 shown in FIG. 6b illustrating voltage dependence of the corresponding SP emission power. In this high-voltage range, electrically-driven SPs were generated, propagated, and scattered at the end of the AgNRs 414, and then converted to far-field photons. FIG. 6c illustrates an exemplary plot 620 showing voltage dependence of the EQE of the RIET SP source, biased at a voltage above the REET current peak (i.e. peak-1 601 shown in FIG. 6a). Two EQE peaks may be observed in this high-voltage range. Their position (peak voltage) may be determined by the optical and electrical processes involved in RIET.

As shown in FIG. 6c, the peak EQE may reach up to 30%, which is a substantial improvement over existing on-chip electrically-driven SP source system. The EQE may be expressed as a product of an internal quantum efficiency (IQE) for the electro-optical transduction and a near-unity excitation probability of SPs, where the IQE is the ratio Γᵢₙₑₗ/(Γᵢₙₑₗ+Γₑₗ) with the inelastic (elastic) transition rate Γᵢₙₑₗ (Γₑₗ) of electrons. Thus, the EQE may be determined by the corresponding IQE, and, in order to gain a high EQE, Γᵢₙₑₗ may be increased while Γₑₗ may be decreased. This may be achieved using the current subject matter's MQW junction layer 406 (shown in FIG. 4), which, as discussed above, may include two “thick” dielectric barrier layers 408, 410 (as shown in FIG. 4). The layers 408, 410 may cause a decrease of Tₑₗ and, at the same time, suppress the REET process at high voltages. Further, at the same voltage, an increase of Γᵢₙₑₗ may be achieved via the RIET process.

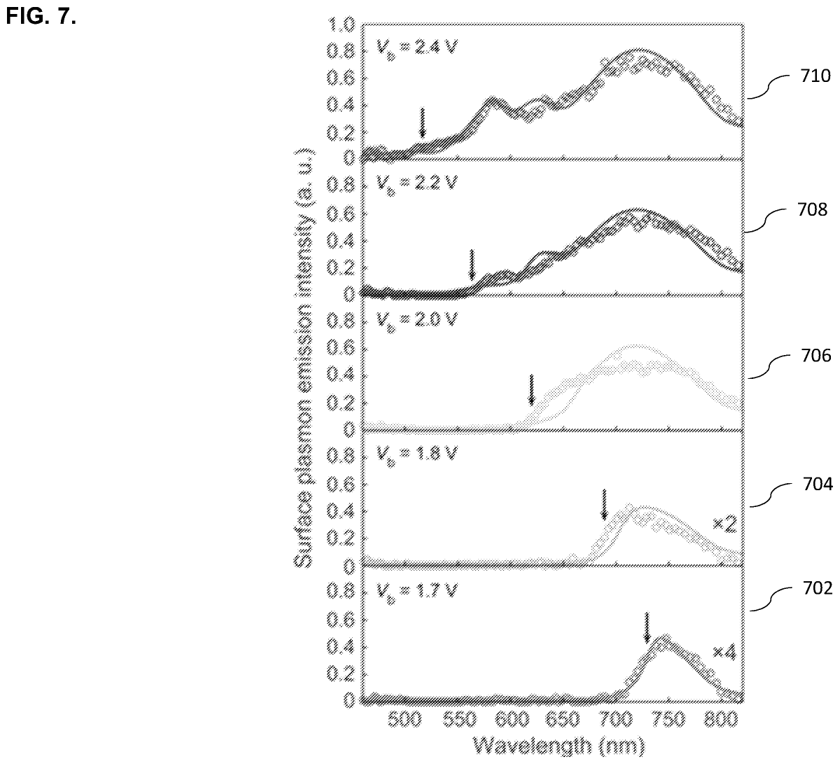

FIG. 7 illustrates exemplary SP emission spectra plots 702-710 of the current subject matter's RIET device at various voltages, according to some experimental implementations of the current subject matter (e.g., where the voltages may be obtained from the corresponding far-field emission spectra). A cutoff frequency vₘₐₓ at a particular voltage is illustrated by an error in each respective plot. The cutoff frequency of IET-based sources may be described by the quantum relation hvₘₐₓ=eV_{b}, where e is the electron charge. The SP radiation power spectrum may be expressed as

$${P}_{S P} ( v , {V}_{b} ) = h v \times {γ}_{inel}^{0} ( v , {V}_{b} ) \times \frac{{ρ}_{o p t}}{{ρ}_{o}} \times {η}_{S P} ( v ) \qquad ( 1 )$$

where γᵢₙₑₗ⁰ is the spectral inelastic transition rate in vacuum, ρ₀ is the vacuum LDOS,

ρₒₚₜ is the device LDOS, and η_{SP} is the SP radiation efficiency.

A spontaneous emission model developed for IET-based sources may be used to calculate γᵢₙₑₗ⁰, where FEM simulations may be applied to determine the LDOS enhancement ρₒₚₜ/ρ₀, while lisp may be determined using a ratio of the SP excitation power ρₛₚ to the total power dissipation pₜₒₜ as follows:

$${η}_{s p} = \frac{{p}_{s p}}{{p}_{t o t}} = \frac{{p}_{s p}}{{p}_{s p} + {p}_{loss} + {p}_{r}} \qquad ( 2 )$$

where the total dissipated power includes the SP excitation part pₛₚ and the absorption loss pₗₒₛₛ by the device materials and the far-field radiative part pᵣ. The far-field radiation efficiency ηᵣ/pₜₒₜ may be low—on the order of 10⁻³. In plots 702-710, the dots illustrate voltage dependence of the SP-emission spectrum for a RIET device and the determined SP radiation power spectra P_{SP}(v, V_{b}) are shown by the solid lines. As shown in Equation 1, the spectra may result from both the electrical properties (i.e., γᵢₙₑₗ⁰(v, V_{b})) and optical response (i.e., ρₒₚₜ/ρ₀×η_{SP}(v)) of the RIET device. The plasmonic resonances of AgNRs may be determine the spectral peaks, which come out only when the applied bias exceeds the corresponding plasmon mode energy, and may be modulated by the wavelength-dependent RIET process.

Thus, as discussed above, the current subject matter's SP sources are capable of generating an EQE up to 30% based on RIETs in an MQW junction. The large well-depth of the MQW provides a plenty of resonant electron states with transition energies covering the entire visible/NIR/mid-infrared frequency range, allowing on-chip plasmonic circuitries for optical communications and information processing in the desired operating window. The working frequency of the RIET device may be determined by the applied external voltages, resonant tunneling configurations, and the designed LDOS, exhibiting its broadband tunability. Further optimization of the MQW junction structure from both material selection and fabrication perfection point of views may improve the EQE.

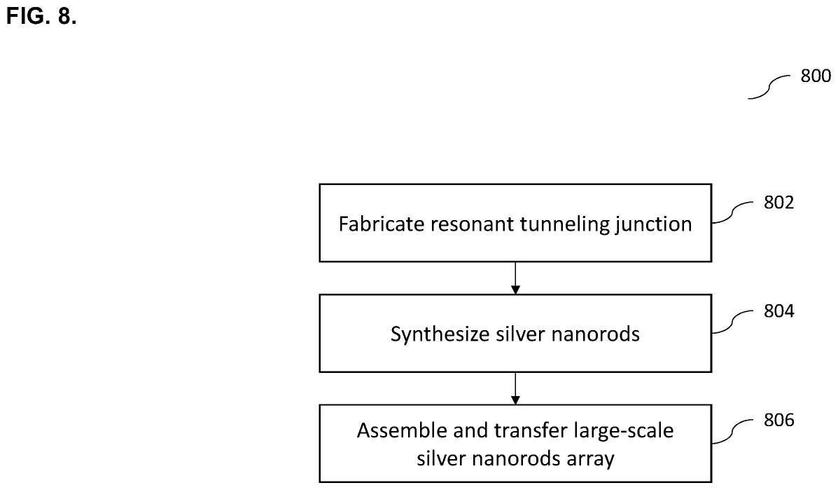

FIG. 8 illustrates an exemplary, non-limiting experimental process 800 for fabricating resonant inelastic electron tunneling devices, according to some implementations of the current subject matter. As can be understood, other processes and/or processes using other parameters may be used. At 802, the resonant tunneling junctions may be fabricated. In some exemplary, non-limiting implementations, for the resonant inelastic electron tunneling devices (as discussed above with regard to FIGS. 1-7), both the bottom electrode layer (e.g., 50-nm TiN) and the above metallic quantum well (MQW) junction layer may be grown on sapphire substrates by the reactive magnetron sputtering technique. For example, a reactive growth temperature of TiN may be set at 350° C. with a N2:Ar gas ratio of 7:3. The Ti target may be used with a power of 200 W. The Al₂O₃ may be deposited in the same chamber as the TiN reactive growth. Its deposition ambiance may be as follows: an Al₂O₃ target may be used, where the temperature for the Al₂O₃ deposition may be set as 350° C., i.e., the same as for the reactive growth of TiN. The deposition power may be set as 150 W with 5-sccm Ar under 5-mT pressure. The deposition speed may be approximately 0.4 nm/min. The cross-sectional morphology of the MQW junction film layers may be characterized by high-resolution transmission electron microscopy (HRTEM). For example, the top electrode, from bottom to top, may include 60-nm Al₂O₃, 5-nm Ti and 150-nm Au. The different working regions may be produced by the photolithography. The silver nanorods (AgNRs) array may be transferred from the water-air interface, as described below (at 806). The 150-nm ITO may be deposited (magnetron sputtering technique) using a 100-W deposition power with 5-sccm Ar under 5-mT pressure.

At 804, the silver nanorods (AgNRs) may be synthesized. For example, the AgNRs may be synthesized by modifying a seed-mediated synthesis of faceted nanorods. First, silver nanocrystal seeds may be made by using a mixture of 1.500 mL of 0.05 M sodium citrate, 0.045 mL of 0.05 M PVP (molecular weight˜55000), 0.150 mL of 0.005 M1-arginine, 0.600 mL of 0.005 M AgNO3 and 18.000 mL of deionized water in a 20-mL vial with a magnetic stirring. Then, the reducing agent 0.24 mL of 0.10 M NaBH4 may be added. The resulting solution may be bright yellow (after few minutes). The bright yellow solution may then be exposed to a blue LED lamp. After exposed about 20 hours, the resulting solution may become bright yellowish orange with a plasmonic peak at 450 nm.

In seed growth step, 6 mL of the prepared seed solution may be centrifuged and re-dispersed in 1.0 mL of deionized water. 12.0 mL of deionized water, 1.6 mL of 0.05 M sodium citrate, and 0.264 mL of 0.05 M PVP (molecular weight˜55000) may be heated to 100° C. in a 20-mL vial on a magnetic stirrer. After temperature equilibration, 1 mL of seed solution may be added followed by 0.005 M silver nitrate. Varying the amount of silver nitrate (0.7-1.2 mL) and the reaction time (30-90 min) may allow producing rods of different length with an aspect ratio up to 3-4 in high yield.

At 806, a large-scale silver nanorods array may be assembled and transferred. For example, to prepare an orderly nanocrystals array, the further purification and surface modification steps may require an as-made AgNRs colloidal solution. A 3-4 ml of as-made AgNRs aqueous solution may be centrifuged for removing small nanocrystals and free ligands (e.g., PVP and citrate). Then, the sediment may be re-dispersed in 0.75-ml deionized water and followed by adding 0.75-ml ethanol. This AgNRs water/ethanol solution may be added into a 1-μM poly(ethylene glycol) methyl ether thiol (PEG-thiol with average Mn˜10000) ethanol solution (20 mg of PEG-thiol+2-ml ethanol) and incubated for 2-3 hours. During the surface modification, original ligand shell (PVP and citrate) coated outside nanorods may be replaced by PEG thiol. After 2-3 hours, the solution may be centrifuged for removing the PVP, citrate and free PEG thiols.

Then, the sediment may be re-dispersed ethanol and this purification process may be repeated three times. The finial sediment may be dispersed in CHCl₃. This colloidal nanocrystal solution may then be added dropwise to the air-water interface of glass petri dish, which gives an isotopically distributed monolayer of silver nanocrystals floating at the air-water interface and the spacing between nanocrystals may be controlled. Nanocrystal monolayers may then be transferred onto the MQW junction layer.

In some implementations, the current subject matter relates to an apparatus (e.g., a surface plasmon source). Such exemplary apparatus is shown in FIGS. 1-5d and discussed above. The apparatus may include a conductive quantum well junction (e.g., layer 106 shown in FIG. 1 and/or layer 406 shown in FIG. 4) that may be positioned between a first electrode (e.g., layer/electrode 104 shown in FIG. 1 or layer/electrode 404 shown in FIG. 4) and a second electrode (e.g., layer/electrode 102 shown in FIG. 1 or layer/electrode 402 shown in FIG. 4). The conductive quantum well junction may be configured to enter into a resonant state to inelastically tunneling one or more electrons (such as through application of electrical energy from an external source).

In some implementations, the current subject matter may include one or more of the following optional features. The conductive quantum well junction may include a first dielectric layer (e.g., layer 108/408 shown in FIGS. 1 and 4, respectively), a third conductive layer (e.g., layer 112/412), and a second dielectric layer (e.g., layer 110/410). The third conductive layer may be positioned between the first dielectric layer and the second dielectric layer, as shown in FIGS. 1 and/or 4. The first dielectric layer may be coupled to the second electrode and the second dielectric layer is coupled to the first electrode.

In some exemplary implementations, the first electrode may be an indium-tin-oxide layer and the second electrode is a titanium-nitride layer.

In some exemplary implementations, the third metallic layer may be a titanium-nitride layer.

The apparatus may also include an energy coupling device (e.g., nanorods 114/414 shown in FIGS. 1 and 4, respectively) that may be positioned between the conductive quantum well junction and the first electrode. The energy coupling device may be configured to support inelastic tunneling of the one or more electrons in the resonant state. Alternatively, or in addition to, the energy coupling device may be positioned between the conductive quantum well junction and the second electrode. Moreover, one or both of the first and second electrodes may include the energy coupling device. As stated above, the energy coupling device includes one or more silver nanorods, metallic nanorods, conductive nanorods, and/or any combination thereof.

In some implementations, the second electrode may be disposed on a substrate (e.g., substrate 411 shown in FIG. 4). The substrate may be a sapphire substrate and/or any material substrate.

An external energy source (e.g., source 120/420 as shown in FIGS. 1 and 4, respectively) may be configured to supply a predetermined potential (as shown in FIG. 3) to cause the conductive quantum well junction to enter into the resonant state for inelastically tunneling the one or more electrons. The external energy source may be coupled to first and second electrodes.

In some implementations, the apparatus may also include a fourth metallic layer (e.g., a gold layer 418 as shown in FIG. 4) and a dielectric layer (e.g., aluminum oxide layer 416 as shown in FIG. 4) disposed between at least a portion of the first electrode and the conductive quantum well junction, as shown in FIG. 4. An external energy source (e.g., source 420 as shown in FIG. 4) may be coupled to the second electrode and the fourth metallic layer.

In some implementations, the conductive quantum well junction may be configured to prevent elastic tunneling of one or more electrons. The inelastic tunneling of the electrons through the conductive quantum well junction layer may be configured to generate light in at least one of the following spectrums: a visible light spectrum, a near infrared light spectrum, mid-infrared light spectrum, and any combination thereof.

In some implementations, the current subject matter relates to an optical apparatus. The apparatus may include a plasmonic device (e.g., shown in FIGS. 1 and 4). The plasmonic device may include a conductive quantum well junction positioned between a first electrode and a second electrode. The conductive quantum well junction may be configured to enter into a resonant state to inelastically tunneling one or more electrons. The optical apparatus may also include an external electrical energy source configured to supply a predetermined potential to cause the conductive quantum well junction to enter into the resonant state for inelastically tunneling the one or more electrons. The inelastic tunneling of the electrons through the plasmonic device may be configured to generate light in at least one of the following spectrums: a visible light spectrum, a near infrared light spectrum, mid-infrared light spectrum, and any combination thereof.

In some implementations, the optical apparatus may include an energy coupling device positioned between the conductive quantum well junction and the first electrode. The energy coupling device may support inelastic tunneling of the electrons in the resonant state. Further, the plasmonic device may include at least one of the following: a nanoLED, a nanolaser, a nanojunction, a plasmonic source, an on-chip electrically-driven plasmonic circuit, a waveguide, a router, a modulator, a detector, and any combination thereof. Moreover, the optical apparatus may include a plurality of plasmonic devices disposed on a single substrate (e.g., as shown in FIG. 5a).

In some implementations, the current subject matter relates to a method for generating light using a plasmonic device. The method may include providing a conductive quantum well junction positioned between a first electrode and a second electrode, applying an electrical potential across the conductive quantum well junction to cause the conductive quantum well junction to enter into a resonant state, inelastically tunneling one or more electrons through the metallic quantum well junction in the resonant state, and generating light in at least one of the following spectrums: a visible light spectrum, a near infrared light spectrum, mid-infrared light spectrum, and any combination thereof.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and sub-combinations of the disclosed features and/or combinations and sub-combinations of several further features disclosed above. In addition, the logic flows depicted in the accompanying figures and/or described herein do not necessarily require the particular order shown, or sequential order, to achieve desirable results. Other implementations can be within the scope of the following claims.

As used herein, the term “user” can refer to any entity including a person or a computer.

Although ordinal numbers such as first, second, and the like can, in some situations, relate to an order; as used in this document ordinal numbers do not necessarily imply an order. For example, ordinal numbers can be merely used to distinguish one item from another. For example, to distinguish a first event from a second event, but need not imply any chronological ordering or a fixed reference system (such that a first event in one paragraph of the description can be different from a first event in another paragraph of the description).

The foregoing description is intended to illustrate but not to limit the scope of the invention, which is defined by the scope of the appended claims. Other implementations are within the scope of the following claims.

1. An apparatus, comprising:
a conductive quantum well junction positioned between a first electrode and a second electrode, the conductive quantum well junction is configured to enter into a resonant state to inelastically tunneling one or more electrons.

2. The apparatus according to claim 1, the conductive quantum well junction including a first dielectric layer, a third conductive layer, and a second dielectric layer, the third conductive layer being positioned between the first dielectric layer and the second dielectric layer.

3. The apparatus according to claim 2, wherein the first dielectric layer is coupled to the second electrode and the second dielectric layer is coupled to the first electrode.

4. The apparatus according to claim 3, wherein the first electrode is an indium-tin-oxide layer.

5. The apparatus according to claim 4, wherein the second electrode is a titanium-nitride layer.

6. The apparatus according to claim 2, wherein the third conductive layer is a titanium-nitride layer.

7. The apparatus according to claim 2, further comprising an energy coupling device positioned between the conductive quantum well junction and the first electrode, the energy coupling device supporting inelastic tunneling of the one or more electrons in the resonant state.

8. The apparatus according to claim 2, further comprising an energy coupling device positioned between the conductive quantum well junction and the second electrode, the energy coupling device supporting inelastic tunneling of the one or more electrons in the resonant state.

9. The apparatus according to claim 7, wherein the energy coupling device includes one or more silver nanorods, metallic nanorods, conductive nanorods, and any combination thereof.

10. The apparatus according to claim 7, wherein at least one of the first and second electrodes includes the energy coupling device.

11. The apparatus according to claim 1, wherein the second electrode is disposed on a substrate.

12. The apparatus according to claim 1, wherein an external energy source is configured to supply a predetermined potential to cause the conductive quantum well junction to enter into the resonant state for inelastically tunneling the one or more electrons.

13. The apparatus according to claim 12, wherein the external energy source is coupled to first and second electrodes.

14. The apparatus according to claim 2, further comprising a fourth metallic layer and a dielectric layer disposed between at least a portion of the first electrode and the conductive quantum well junction.

15. The apparatus according to claim 14, wherein an external energy source is coupled to the second electrode and the fourth metallic layer.

16. The apparatus according to claim 2, wherein the conductive quantum well junction is configured to prevent elastic tunneling of one or more electrons.

17. The apparatus according to claim 16, wherein the inelastic tunneling of the one or more electrons through the conductive quantum well junction is configured to generate light in at least one of the following spectrums: a visible light spectrum, a near infrared light spectrum, mid-infrared light spectrum, and any combination thereof.

18. An optical apparatus, comprising:
a plasmonic device including
a conductive quantum well junction positioned between a first electrode and a second electrode, the conductive quantum well junction is configured to enter into a resonant state to inelastically tunneling one or more electrons; and
an external electrical energy source is configured to supply a predetermined potential to cause the conductive quantum well junction to enter into the resonant state for inelastically tunneling the one or more electrons;
wherein the inelastic tunneling of the one or more electrons through the plasmonic device is configured to generate light in at least one of the following spectrums: a visible light spectrum, a near infrared light spectrum, mid-infrared light spectrum, and any combination thereof.

19. The optical apparatus according to claim 18, further comprising an energy coupling device positioned between the conductive quantum well junction and the first electrode, the energy coupling device supporting inelastic tunneling of the one or more electrons in the resonant state.

20. The optical apparatus according to claim 19, wherein the plasmonic device includes at least one of the following: a nanoLED, a nanolaser, a nanojunction, a plasmonic source, an on-chip electrically-driven plasmonic circuit, a waveguide, a router, a modulator, a detector, and any combination thereof.

21. The optical apparatus according to claim 20, further comprising a plurality of plasmonic devices disposed on a single substrate.

22. A method, comprising:
providing a conductive quantum well junction positioned between a first electrode and a second electrode,
applying an electrical potential across the conductive quantum well junction to cause the conductive quantum well junction to enter into a resonant state;
inelastically tunneling one or more electrons through the conductive quantum well junction in the resonant state; and
generating light in at least one of the following spectrums: a visible light spectrum, a near infrared light spectrum, mid-infrared light spectrum and any combination thereof.
